(19) United States
(12) Patent Application Publication
(10) Pub. No.: US 2008/0113515 A1
(43) Pub. Date: May 15, 2008

(54) Methods of Forming Semiconductor Devices

(75) Inventors: Hyun-Chul Kim, Seoul (KR); Sung-Il Cho, Seoul (KR); Eun-Young Kang, Seoul (KR); Yong-Hyun Kwon, Gyeonggi-do (KR); Jae-Seung Hwang, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/874,267

(22) Filed: Oct. 18, 2007

(30) Foreign Application Priority Data
Nov. 10, 2006 (KR) 2006-111181

(51) Int. Cl. H01L 21/302

(52) U.S. Cl. 438/702

(57) ABSTRACT

A method of forming a semiconductor device is provided. The method includes preparing a semiconductor substrate to include a cell region and a peripheral region and forming a first mask layer on the semiconductor substrate. First hard mask patterns that are configured to expose the first mask layer are formed on the first mask layer in the cell region. A second mask layer that is configured to conformably cover the first hard mask patterns is formed. A second hard mask pattern is formed between the first hard mask patterns, wherein the second hard mask pattern is configured to contact a lateral surface of the second mask layer. The second mask layer interposed between the first hard mask patterns and the second hard mask pattern is removed. A plurality of trenches are etched in the semiconductor substrate of the cell region using the first hard mask patterns and the second hard mask pattern as a mask.

### CROSS-REFERENCE TO RELATED APPLICATIONS

This U.S. non-provisional patent application claims priority under 35 U.S.C §119 of Korean Patent Application 2006-111181 filed on Nov. 10, 2006, the entire contents of which are hereby incorporated by reference.

### BACKGROUND

The present invention relates to semiconductor devices, and more particularly, to methods of forming semiconductor devices.

As the integration density of semiconductor devices increases, a channel length may decrease. Thus, various problems, such as a short channel effect and a punchthrough, may occur. In order to solve these problems, a research has been conducted on structures and methods for increasing the channel length of a highly integrated semiconductor device. For example, a transistor using both a sidewall and a bottom surface of a trench formed in a semiconductor substrate as a channel region has been proposed. A process of forming the trench may include forming a hard mask layer on the semiconductor substrate. A photoresist pattern may be formed on the hard mask layer. The hard mask layer may be patterned using the photoresist pattern as a mask, thereby forming a hard mask pattern. The trench may be formed using the hard mask pattern as a mask.

As the linewidth of a gate electrode has gotten smaller in recent semiconductor developments, photoresist patterns including a fine opening may be increasingly desirable. Forming the photoresist pattern having the fine opening may be difficult, however, due to the exposure and development limits.

### SUMMARY OF THE INVENTION

Embodiments of the present invention are directed to methods of forming a semiconductor device. In some embodiments, a method for forming a semiconductor device includes preparing a semiconductor substrate to include a cell region and a peripheral region, forming a first mask layer on the semiconductor substrate, and forming first hard mask patterns on the first mask layer in the cell region, the first hard mask patterns configured to expose the first mask layer. Methods may also include forming a second mask layer that is configured to conformably cover the first hard mask patterns, forming a second hard mask pattern between the first hard mask patterns, the second hard mask pattern configured to contact a lateral surface of the second musk layer, removing the second mask layer interposed between the first hard mask patterns and the second hard mask pattern, and etching multiple trenches in the semiconductor substrate of the cell region using the first hard mask patterns and the second hard mask pattern as a mask.

In some embodiments, forming the second mask layer includes using an atomic layer deposition (ALD) technique and/or a chemical vapor deposition (CVD) technique. In some embodiments, the first mask layer and the second mask layer include an etch selectivity with respect to the first hard mask patterns and the second hard mask pattern. Some embodiments provide that the first mask layer and the second mask layer include a silicon oxide layer and the first hard mask patterns and the second hard mask pattern include a silicon nitride layer.

In some embodiments, forming the first hard mask patterns includes partially etching the first mask layer, wherein an etched thickness of the first mask layer is equal to a thickness of the second mask layer. In some embodiments, forming the second hard mask pattern includes forming a second hard mask layer that is configured to cover the second mask layer and planarizing the second hard mask layer to expose top surfaces of the first hard mask patterns. Such embodiments may further provide that the second hard mask pattern includes a thickness that is substantially equal to a first hard mask patterns thickness.

Some embodiments include forming a gate electrode in at least one of the multiple trenches, removing the first hard mask patterns and the second hard mask pattern, and removing the first mask layer and the second mask layer. In some embodiments, the gate electrode includes titanium nitride (TiN).

Some embodiments include forming a conductive layer on the semiconductor substrate before forming the first mask layer. Methods according to some embodiments may include forming a cell gate electrode in at least one of the multiple trenches, removing the first hard mask patterns and the second hard mask pattern, removing the first mask layer and the second mask layer, forming a photoresist pattern on the conductive layer in the peripheral region, and etching the conductive layer using the photoresist pattern as a mask to form a peripheral gate electrode.

In some embodiments, forming the peripheral gate electrode includes removing the conductive layer from the cell region. In some embodiments, the first mask layer and the second mask layer include an etch selectivity with respect to the conductive layer. In some embodiments, the first mask layer and the second mask layer include a silicon oxide layer, and the conductive layer includes a polysilicon layer.

Some embodiments of a method of forming a semiconductor device include forming an isolation layer in a semiconductor substrate, forming a first mask layer on the semiconductor substrate, forming a first hard mask layer on the first mask layer, and forming a photoresist pattern on the first hard mask layer. Embodiments may include etching the first hard mask layer using the first photoresist pattern as a mask to form multiple first hard mask patterns, removing the first photoresist pattern, forming a second mask layer that is configured to conformably cover the multiple first hard mask patterns, and forming a second hard mask pattern interposed between ones of the multiple first hard mask patterns and that is configured to contact a lateral surface of the second mask layer. Some embodiments include removing the second hard mask pattern interposed between the ones of the multiple first hard mask patterns and etching a trench using the first hard mask patterns and the second hard mask pattern as masks.

In some embodiments, etching the first hard mask layer includes partially etching the first mask layer to a first thickness. In some embodiments, forming the second mask layer includes forming the second mask layer to the first thickness. In some embodiments, forming the second hard mask pattern includes forming a second hard mask layer that is configured to cover the second mask layer. Forming the second hard mask pattern according to some embodiments may include planarizing the second hard mask layer to expose top surfaces of the plurality of first hard mask patterns. Some embodiments provide that forming the second hard mask pattern includes forming a second hard mask pattern that comprises the first thickness.

In some embodiments, etching the trench includes etching the trench to a first thickness that is substantially smaller than an interval between the plurality of first hard mask patterns.

### BRIEF DESCRIPTION OF THE DRAWINGS

FIGS. 1A through 1G are cross-sectional views illustrating methods of forming semiconductor devices according to some embodiments of the present invention.

FIGS. 2A through 2I are cross-sectional views illustrating methods of forming semiconductor devices according some other embodiments of the present invention.

### DETAILED DESCRIPTION OF PREFERRED EMBODIMENTS

The present invention will now be described more fully hereinafter with reference to the accompanying drawings, in which embodiments of the invention are shown. This invention, however, should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present.

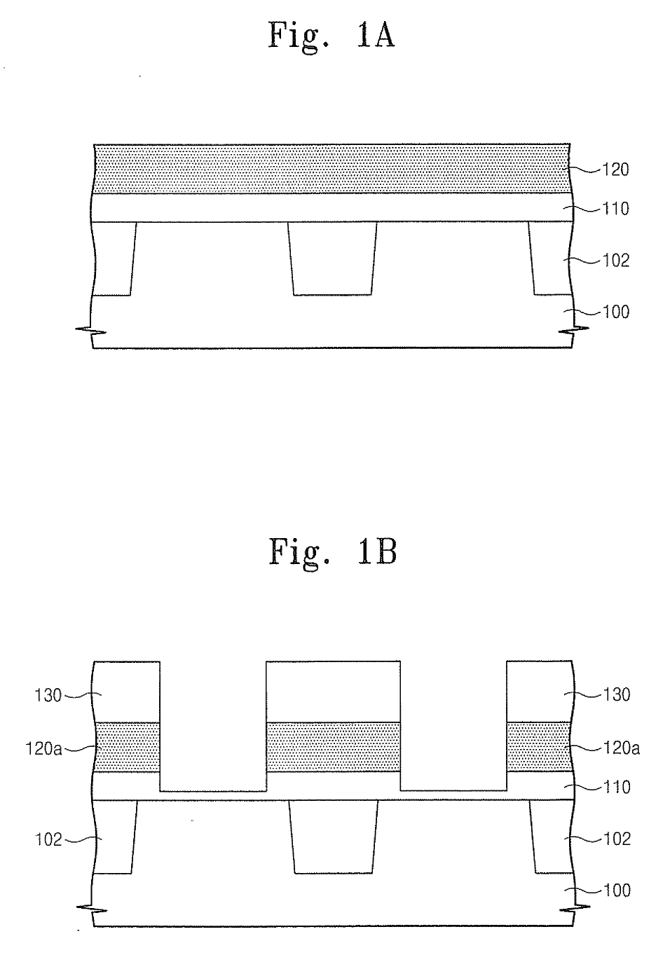

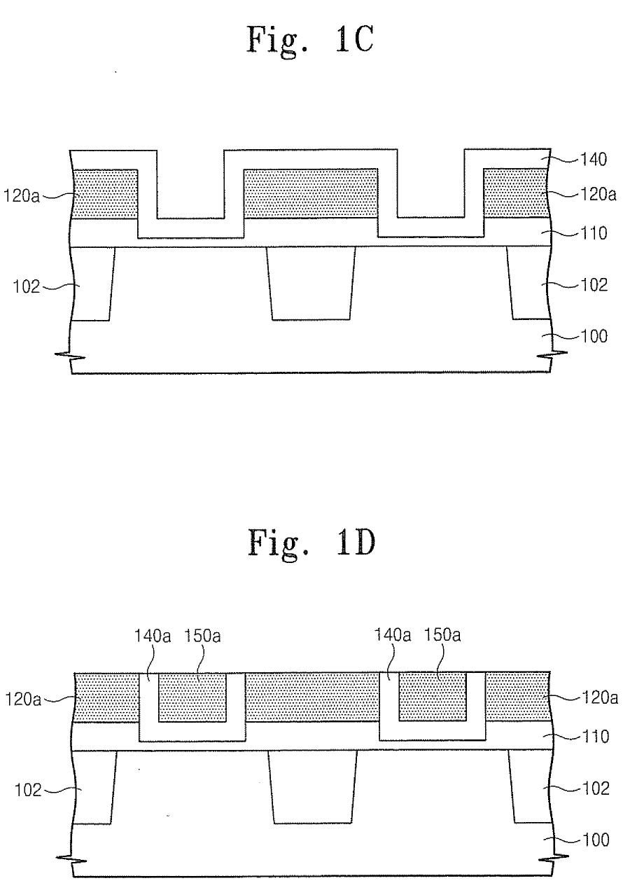

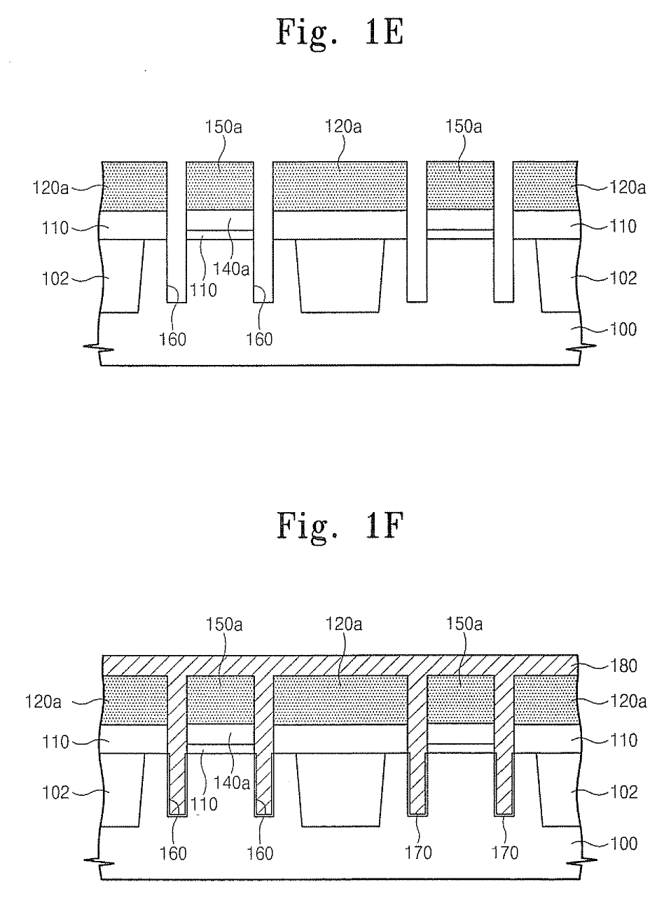

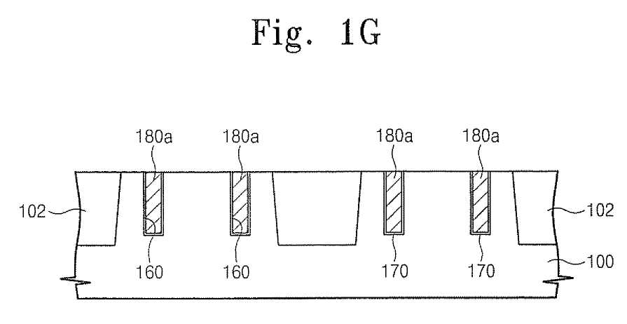

FIGS. 1A through 1G are cross-sectional views illustrating methods of forming semiconductor devices according to some embodiments of the present invention.

Referring to FIG. 1A, a device isolation layer 102 may be formed in a semiconductor substrate 100 to define an active region. The formation of the device isolation layer 102 may include forming a trench in the semiconductor substrate 100 and filling the trench with an insulating layer. A first mask layer 110 may be formed on the semiconductor substrate 100. In some embodiments, the first mask layer 110 may include a silicon oxide layer obtained using a chemical vapor deposition (CVD) technique. A first hard mask layer 120 may be formed on the first mask layer 110. According to some embodiments, the first hard mask layer 120 may include a silicon nitride layer obtained using a CVD technique.

Referring to FIG. 1B, a first photoresist pattern 130 may be formed on the first hard mask layer 120. The first hard mask layer 120 may be etched using the first photoresist pattern 130 as a mask, thereby forming first hard mask patterns 120a. The formation of the first hard mask patterns 120a may include partially etching the first mask layer 110. In some embodiments, the etched thickness of the first mask layer 110 may be equal to the thickness of a second mask layer 140 that will be described later.

Referring to FIG. 1C, the first photoresist pattern 130 may be removed, and the second mask layer 140 may then be formed to conformably cover the first hard mask patterns 120a. In some embodiments, the second mask layer 130 may be formed using an atomic layer deposition (ALD) or CVD technique. Since the ALD or CVD technique may be used to improve step coverage, the second mask layer 140 may be formed to a uniform thickness. In some embodiments, the second mask layer 140 may be formed to a thickness equal to the etched thickness of the first mask layer 110.

Referring to FIG. 1D, a second hard mask pattern 150a may be formed between the first hard mask patterns 120a and brought into contact with a lateral surface of the second mask layer 140. In some embodiments, the formation of the second hard mask pattern 150a may include forming a second hard mask layer to cover the second mask layer 140 and planarizing the second hard mask layer to expose top surfaces of the first hard mask patterns 120a. The formation of the second hard mask pattern 150a may include forming a second mask pattern 140a. In some embodiments, the thickness of the second hard mask pattern 150a may be substantially equal to that of the first hard mask patterns 120a. This result may arise from an etched thickness of the first mask layer 110 being substantially equal to the thickness of the second mask layer 140.

Referring to FIG. 1E, the second mask pattern 140a interposed between the first hard mask patterns 120a and the second hard mask pattern 150a may be removed. The removal of the second mask pattern 140a may include removing the first mask layer 110 to expose the semiconductor substrate 100. The second mask pattern 140a and the first mask layer 110 may have an etch selectivity with respect to the first hard mask patterns 120a and the second hard mask pattern 150a. In this regard, “a” having an etch selectivity with respect to “b” means that it is possible to etch “a” while minimizing the etching of “b” or to etch “b” while minimizing the etching of “a”. For example, the first hard mask patterns 120a and the second hard mask pattern 150a may be formed of a silicon nitride layer, while the first mask layer 110 and the second mask pattern 140a may be formed of a silicon oxide layer.

An etching process may be performed on the semiconductor substrate 100 using the first hard mask patterns 120a and the second hard mask patterns 150a as masks. In this manner, trenches 160 may be formed. In some embodiments, the trenches 160 may have a width equal to the thickness of the second mask pattern 140a. According to some embodiments of the present invention, the trenches 160 may be formed to a width substantially smaller than an interval between the first photoresist patterns 130.

Referring to FIG. 1F, a gate insulating layer 170 may be formed in the trenches 160. In some embodiments, the gate insulating layer 170 may include a thermal oxide layer obtained using a thermal oxidation process. A gate conductive layer 180 is formed to fill the trenches 160. The gate conductive layer 180 may be formed of titanium nitride (TiN) that has a good gap filling characteristic.

Referring to FIG. 1G, an etchback process may be performed on the gate conductive layer 180, thereby forming a gate electrode 180a in the trenches 160. In some embodiments, the etchback process may include a dry etching process. The first hard mask patterns 120a and the second hard mask pattern 150a may be removed. The first hard mask patterns 120a and the second hard mask pattern 150a may have the same thickness and an etch selectivity with respect to the first mask layer 110 and the second mask pattern 140a. Accordingly, the first mask layer 110 may form a planar top surface with the second mask pattern 140a.

The first mask layer 110 and the second mask pattern 140a may be removed. In some embodiments, the thickness of the first mask layer 110 interposed between the first hard mask patterns 120a and the semiconductor substrate 100 may be equal to the sum of the thicknesses of the first mask layer 110 and the second mask pattern 140a that is interposed between the second hard mask pattern 150a and the semiconductor substrate 100. In this regard, even if the first mask layer 110 and the second mask pattern 140a are removed, the semiconductor substrate 100 may have a uniform surface.

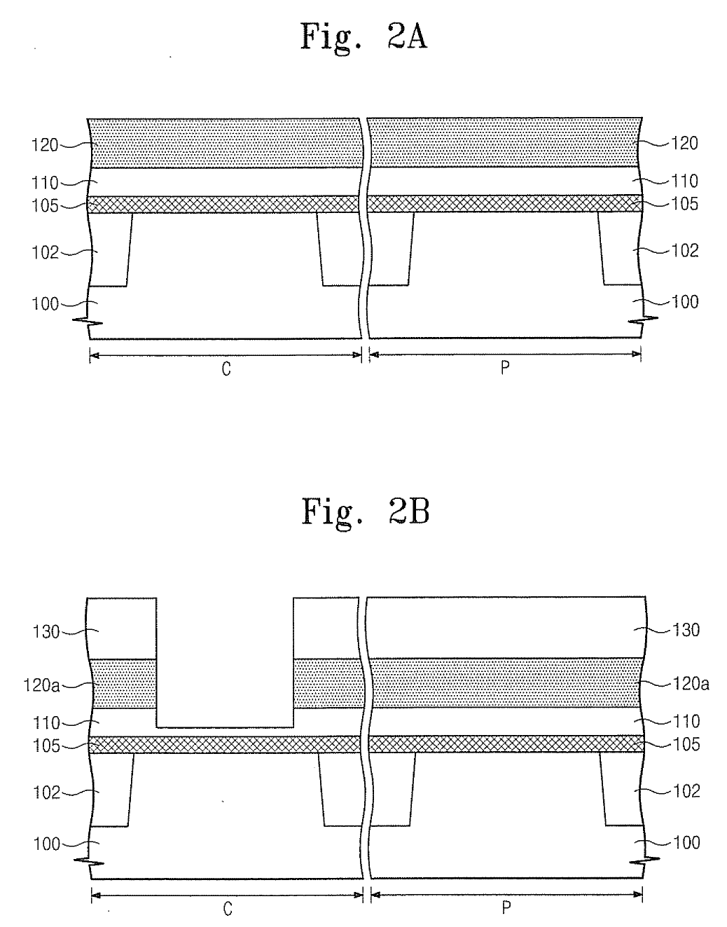

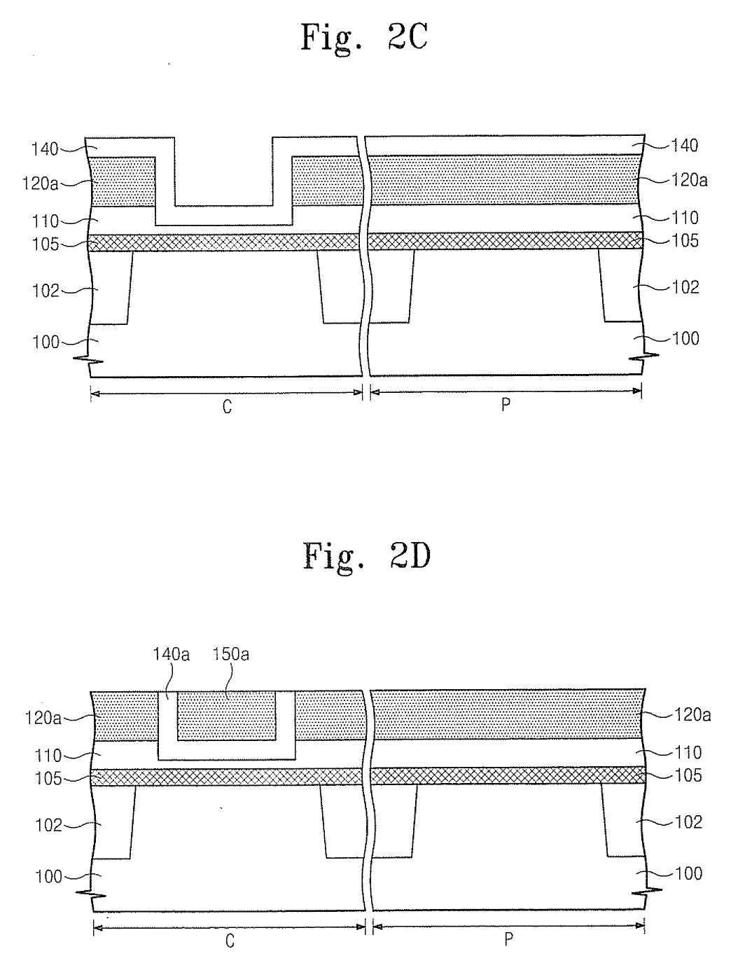

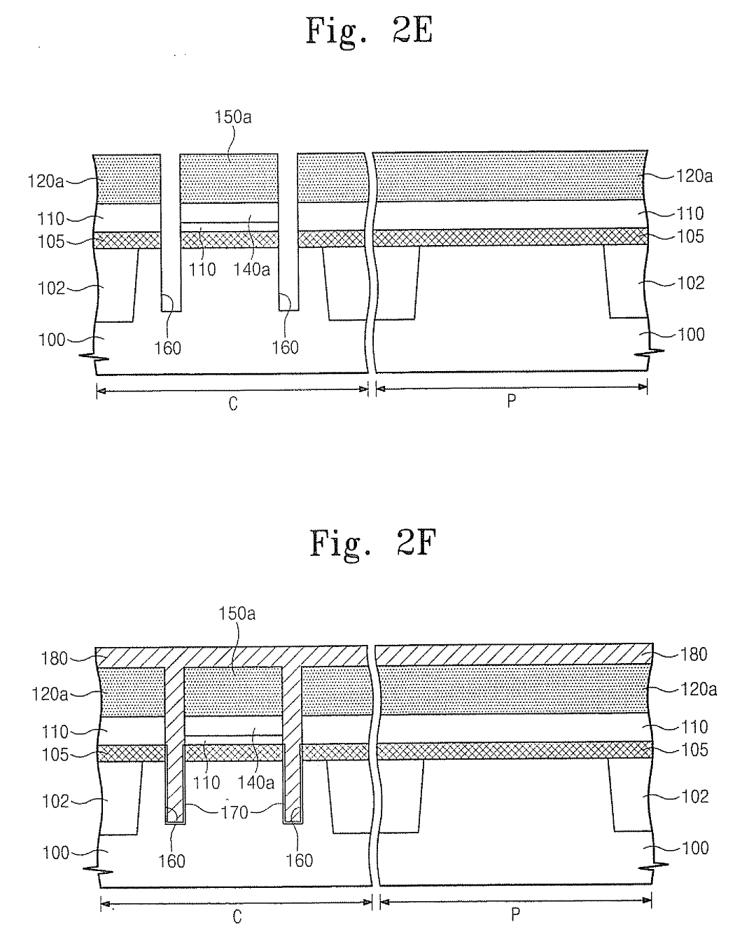

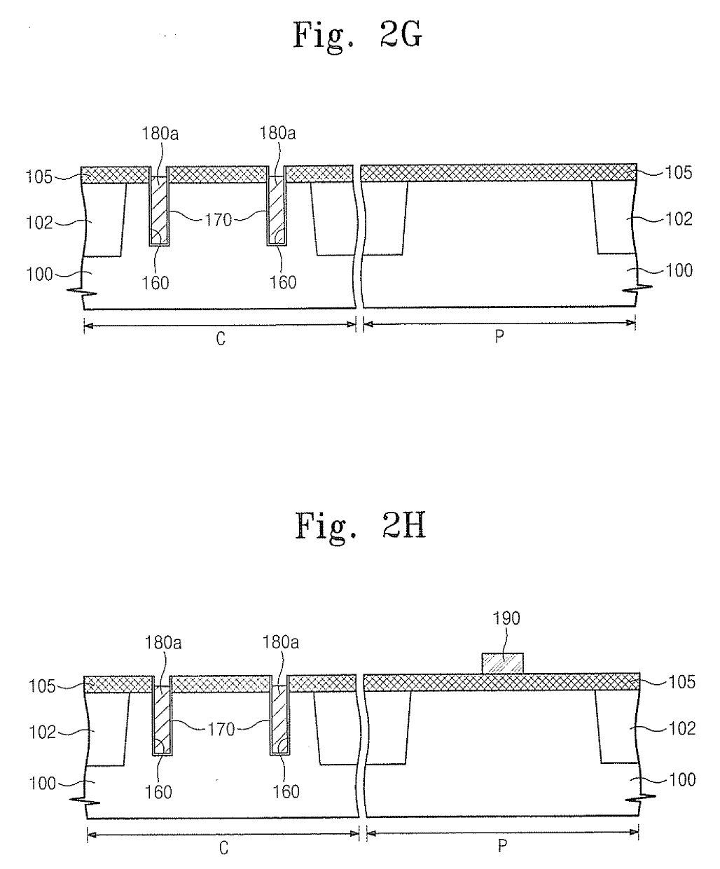

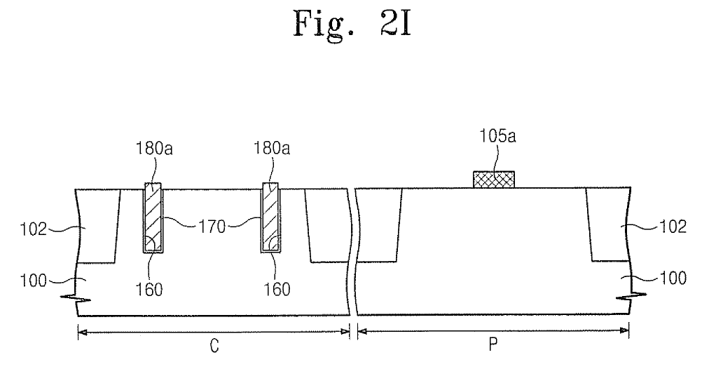

FIGS. 2A through 2I are cross-sectional views illustrating methods of forming semiconductor devices according to some embodiments of the present invention. Referring to FIG. 2A, a semiconductor substrate 100 may include a cell region C and a peripheral region P. A device isolation layer 102 may be formed in the semiconductor substrate 100 to define an active region. In some embodiments, the formation of the device isolation layer 102 may include forming a trench in the semiconductor substrate 100 and filling the trench with an insulating layer. A conductive layer 105 may be formed on the semiconductor substrate 100. In some embodiments, the conductive layer 105 may include a polysilicon (poly-Si) layer. A first mask layer 110 may be formed on the conductive layer 105. In some embodiments, the first mask layer 110 may include a silicon oxide layer obtained using a CVD technique. A first hard mask layer 120 maybe formed on the first mask layer 110. In some embodiments, the first hard mask layer 120 may include a silicon nitride layer obtained using a CVD technique.

Referring to FIG. 2B, a first photoresist pattern 130 may be formed on the first hard mask layer 120. The first hard mask layer 120 may be etched using the first photoresist pattern 130 as a mask, thereby forming first hard mask patterns 120a. In some embodiments, the formation of the first hard mask patterns 120a may include partially etching the first mask layer 110. In some embodiments, the etched thickness of the first mask layer 110 may be equal to the thickness of a second mask layer 140 as described below.

Referring to FIG. 2C, the first photoresist pattern 130 may be removed and a second mask layer 340 may then be formed to conformably cover the first hard mask patterns 120a. In some embodiments, the second mask layer 140 may be formed using an ALD or CVD technique. Since the ALD or CVD technique may be used to improve step coverage, the second mask layer 140 may be formed to a uniform thickness. Some embodiments provide that the second mask layer 140 may be formed to a thickness equal to the etched thickness of the first mask layer 110.

Referring to FIG. 2D, a second hard mask pattern 150a may be formed between the first hard mask patterns 120a and brought into contact with a lateral surface of the second mask layer 140. In some embodiments, the formation of the second hard mask pattern 150a may include forming a second hard mask layer to cover the second mask layer 140 and planarizing the second hard mask layer to expose top surfaces of the first hard mask patterns 120a. The formation of the second hard mask pattern 150a may include forming a second mask pattern 140a. The thickness of the second hard mask pattern 150a may be substantially equal to that of the first hard mask patterns 120a. This result arises from the etched thickness of the first mask layer 110 being substantially equal to the thickness of the second mask layer 140.

Referring to FIG. 2E, the second mask pattern 140a interposed between the first hard mask patterns 120a and the second hard mask pattern 150a may be removed. In some embodiments, the removal of the second mask pattern 140a may include removing the first mask layer 110 to expose the semiconductor substrate 100. The second mask pattern 140a and the first mask layer 110 may have an etch selectivity with respect to the first hard mask patterns 120a and the second hard mask pattern 150a. In this regard, “a” having an etch selectivity with respect to “b” means that it is possible to etch “a” while minimizing the etching of “b” or to etch “b” while minimizing the etching of “a”. For example, the first hard mask patterns 120a and the second hard mask pattern 150a may be formed of a silicon nitride layer, while the first mask layer 110 and the second mask pattern 140a may be formed of a silicon oxide layer.

An etching process may be performed on the conductive layer 105 and the semiconductor substrate 100 using the first hard mask patterns 120a and the second hard mask patterns 150a as masks, thereby forming trenches 160 in the cell region C. In some embodiments, the trenches 160 may have a width equal to the thickness of the second mask pattern 140a. According to some embodiments of the present invention, the trenches 160 may be formed to a width substantially smaller than an interval between the first photoresist patterns 130.

Referring to FIG. 2F, a gate insulating layer 170 may be formed in the trenches 160. In some embodiments, the gate insulating layer 170 may include a thermal oxide layer obtained using a thermal oxidation process. A gate conductive layer 180 may be formed to fill the trenches 160. In some embodiments, the gate conductive layer 180 may be formed of titanium nitride (TiN) that has a good gap filling characteristic.

Referring to FIG. 2G, an etchback process may be performed on the gate conductive layer 180, thereby forming a cell gate electrode 180a in the trenches 160. In some embodiments, the etchback process may include a dry etching process. The first hard mask patterns 120a and the second hard mask pattern 150a may be removed. In some embodiments, the first hard mask patterns 120a and the second hard mask pattern 150a may have the same thickness and an etch selectivity with respect to the first mask layer 110 and the second mask pattern 140a. Accordingly, the first mask layer 110 may form a planar top surface with the second mask pattern 140a.

The first mask layer 110 and the second mask pattern 140a may be removed. In some embodiments, the first mask layer 110 and the second mask pattern 140a may have an etch selectivity with respect to the conductive layer 105. For instance, the first mask layer 110 and the second mask pattern 140a may be formed of a silicon oxide layer, while the conductive layer 105 may be formed of a poly-Si layer. Thus, even if the first mask layer 110 and the second mask pattern 140a are removed, the conductive layer 105 may have a uniform surface.

Referring to FIG. 2H, a metal layer (not shown) may be formed on the conductive layer 105. The metal layer may be formed of tungsten or tungsten silicide. A second photoresist pattern 190 maybe formed on the conductive layer 105 in the peripheral region P.

Referring to FIG. 2I, the conductive layer 105 may be etched using the second photoresist pattern 190 as a mask, thereby forming a peripheral gate electrode 105a. Before forming the conductive layer 105, a peripheral gate insulating layer (not shown) may be formed on the semiconductor substrate 100. The formation of the peripheral gate electrode 105a may include removing the conductive layer 105 from the cell region C. Since the conductive layer 105 formed in the cell region C has a uniform thickness, the semiconductor substrate 100 disposed in the cell region C may have a substantially uniform surface.

According to the embodiments of the present invention, a fine gate electrode may be formed by a mask layer that conformably covers a hard mask pattern. In some embodiments, the thicknesses of hard mask patterns and the mask layer may be controlled such that a semiconductor substrate adjacent to the gate electrode can have a substantially uniform surface. In this regard, a semiconductor device having the fine gate electrode and the semiconductor substrate with a substantially uniform surface may be formed.

Although the present invention has been described in terms of specific embodiments, the present invention is not intended to be limited by the embodiments described herein. Thus, the scope may be determined by the following claims.

What is claimed is:

1. A method of forming a semiconductor device, comprising:
preparing a semiconductor substrate to include a cell region and a peripheral region;
forming a first mask layer on the semiconductor substrate;
forming first hard mask patterns that are configured to expose the first mask layer, on the first mask layer in the cell region;
forming a second mask layer that is configured to conformably cover the first hard mask patterns;
forming a second hard mask pattern that is configured to contact a lateral surface of the second mask layer, between the first hard mask patterns;
removing the second mask layer interposed between the first hard mask patterns and the second hard mask pattern; and
etching a plurality of trenches in the semiconductor substrate of the cell region using the first hard mask patterns and the second hard mask pattern as a mask.

2. The method as recited in claim 1, wherein forming the second mask layer comprises using an atomic layer deposition (ALD) technique and/or a chemical vapor deposition (CVD) technique.

3. The method as recited in claim 1, wherein the first mask layer and the second mask layer comprise an etch selectivity with respect to the first hard mask patterns and the second hard mask pattern.

4. The method as recited in claim 3, wherein the first mask layer and the second mask layer comprise a silicon oxide layer and the first hard mask patterns and the second hard mask pattern comprise a silicon nitride layer.

5. The method as recited in claim 1, wherein forming the first hard mask patterns comprises partially etching the first mask layer,
wherein an etched thickness of the first mask layer is equal to a thickness of the second mask layer.

6. The method as recited in claim 5, wherein forming the second hard mask pattern comprises:
forming a second hard mask layer that is configured to cover the second mask layer; and
planarizing the second hard mask layer to expose top surfaces of the first hard mask patterns,
wherein the second hard mask pattern comprises a thickness that is substantially equal to a first hard mask patterns thickness.

7. The method as recited in claim 6, further comprising:
forming a gate electrode in at least one of the plurality of trenches;
removing the first hard mask patterns and the second hard mask pattern; and
removing the first mask layer and the second mask layer.

8. The method as recited in claim 7, wherein the gate electrode comprises titanium nitride (TiN).

9. The method as recited in claim 1, further comprising forming a conductive layer on the semiconductor substrate before forming the first mask layer.

10. The method as recited in claim 9, further comprising:
forming a cell gate electrode in at least one of the plurality of trenches;
removing the first hard mask patterns and the second hard mask pattern;
removing the first mask layer and the second mask layer;
forming a photoresist pattern on the conductive layer in the peripheral region; and
etching the conductive layer using the photoresist pattern as a mask to form a peripheral gate electrode.

11. The method as recited in claim 10, wherein forming the peripheral gate electrode comprises removing the conductive layer from the cell region.

12. The method as recited in claim 10, wherein the first mask layer and the second mask layer comprise an etch selectivity with respect to the conductive layer.

13. The method as recited in claim 12, wherein the first mask layer and the second mask layer comprise a silicon oxide layer, and the conductive layer comprises a polysilicon layer.

14. A method of forming a semiconductor device, comprising:
forming an isolation layer in a semiconductor substrate;
forming a first mask layer on the semiconductor substrate;
forming a first hard mask layer on the first mask layer;
forming a photoresist pattern on the first hard mask layer;
etching the first hard mask layer using the first photoresist pattern as a mask to form a plurality of first hard mask patterns;
removing the first photoresist pattern;
forming a second mask layer that is configured to conformably cover the plurality of first hard mask patterns;
forming a second hard mask pattern interposed between ones of the plurality of first hard mask patterns and that is configured to contact a lateral surface of the second mask layer;
removing the second hard mask pattern interposed between the ones of the plurality of first hard mask patterns; and
etching a trench using the first hard mask patterns and the second hard mask pattern as masks.

15. The method as recited in claim 14, wherein etching the first hard mask layer comprises partially etching the first mask layer to a first thickness.

16. The method as recited in claim 15, wherein forming the second mask layer comprises forming the second mask layer to the first thickness.

17. The method as recited in claim 14, wherein forming the second hard mask pattern comprises forming a second hard mask layer that is configured to cover the second mask layer.

18. The method as recited in claim 17, wherein forming the second hard mask pattern further comprises planarizing the second hard mask layer to expose top surfaces of the plurality of first hard mask patterns.

19. The method as recited in claim 18, wherein forming the second hard mask pattern further comprises forming a second hard mask pattern that comprises the first thickness.

20. The method as recited in claim 14, wherein etching the trench comprises etching the trench to a first thickness that is substantially smaller than an interval between the plurality of first hard mask patterns.
